(19) United States
(12) Patent Application Publication
(10) Pub. No.: US 2015/0255143 A1
(43) Pub. Date: Sep. 10, 2015

(54) SEMICONDUCTOR DEVICE

(71) Applicant: Kabushiki Kaisha Toshiba, Minato-ku (JP)

(72) Inventor: Koji KUROKI, Hachioji-shi (JP)

(73) Assignee: Kabushiki Kaisha Toshiba, Minato-ku (JP)

(21) Appl. No.: 14/301,505

(22) Filed: Jun. 11, 2014

Related U.S. Application Data
(60) Provisional application No. 61/948,393, filed on Mar. 5, 2014.

(51) Int. Cl. G11C 11/4074

(52) U.S. Cl. CPC G11C 11/4074

(57) ABSTRACT

According to an embodiment, a semiconductor device includes a first pull-up driver, a first pull-down driver, a second pull-up driver and a second pull-down driver. The first pull-up driver is configured to pull up a voltage of a signal output terminal, whose ON resistance is capable of being adjusted to a predetermined reference resistance value. The first pull-down driver is configured to pull down the voltage of the signal output terminal, whose ON resistance is capable of being adjusted to the reference resistance value. The second pull-up driver is configured to pull up the voltage of the signal output terminal, whose ON resistance is capable of being adjusted to n times the reference resistance value. The second pull-down driver is configured to pull down the voltage of the signal output terminal, whose ON resistance is capable of being adjusted to the n times the reference resistance value.

### CROSS REFERENCE TO RELATED APPLICATIONS

This application is based upon and claims the benefit of priority from the prior U.S. Provisional Patent Application No. 61/948,393, filed on Mar. 5, 2014, the entire contents of which are incorporated herein by reference.

### FIELD

Embodiments described herein relate generally to a semiconductor device.

### BACKGROUND

In a semiconductor memory device such as a DDR3-SDRAM (Double Data Rate 3-Synchronous Dynamic Random Access Memory), calibration (ZQ calibration) is performed on an output buffer for outputting read-out data signals and the like. In this calibration, the impedance on the pull-up side of the output buffer and the impedance on the pull-down side are adjusted to match the resistance value of an external resistor RZQ. The impedance on the pull-up side of the output buffer and the impedance on the pull-down side may thereby be adjusted to approximately the same values even when there is a change in the process, the power supply voltage or the temperature. Accordingly, a high-speed read-out operation may be stably performed.

Such an output buffer includes a plurality of drivers that are commonly connected to one signal output terminal. Desirable impedance or termination resistance is realized by controlling the number of drivers to be operated.

### BRIEF DESCRIPTION OF THE DRAWINGS

FIG. 1 is a block diagram showing a schematic configuration of a semiconductor device according to a first embodiment.

FIG. 2 is a circuit diagram of the drivers of the semiconductor device of FIG. 1.

FIG. 3 is a block diagram showing a schematic configuration of a semiconductor device according to the second embodiment.

FIG. 4 is a circuit diagram of drivers of the semiconductor device of FIG. 3.

FIG. 5 is another circuit diagram of the drivers of the semiconductor device of FIG. 3.

FIG. 6 is further another circuit diagram of the drivers of the semiconductor device of FIG. 3.

FIG. 7 is a block diagram showing a schematic configuration of a semiconductor device according to the third embodiment.

FIG. 8 is a circuit diagram of the drivers of the semiconductor device of FIG. 7.

FIG. 9 is a block diagram showing a schematic configuration of a semiconductor device of a comparative example.

### DETAILED DESCRIPTION

According to an embodiment, a semiconductor device includes a first pull-up driver, a first pull-down driver, a second pull-up driver and a second pull-down driver. The first pull-up driver is configured to pull up a voltage of a signal output terminal according to a corresponding pull-up signal, whose ON resistance at a time of pulling up is capable of being adjusted to a predetermined reference resistance value. The first pull-down driver is configured to pull down the voltage of the signal output terminal according to a corresponding pull-down signal, whose ON resistance at a time of pulling down is capable of being adjusted to the reference resistance value. The second pull-up driver is configured to pull up the voltage of the signal output terminal according to a corresponding pull-up signal, whose ON resistance at a time of pulling up is capable of being adjusted to n times the reference resistance value, where n is an integer of two or more. The second pull-down driver is configured to pull down the voltage of the signal output terminal according to a corresponding pull-down signal, whose ON resistance at a time of pulling down is capable of being adjusted to the n times the reference resistance value.

Before describing the embodiments of the present invention, circumstances leading to completion of the present invention by the inventor will be described.

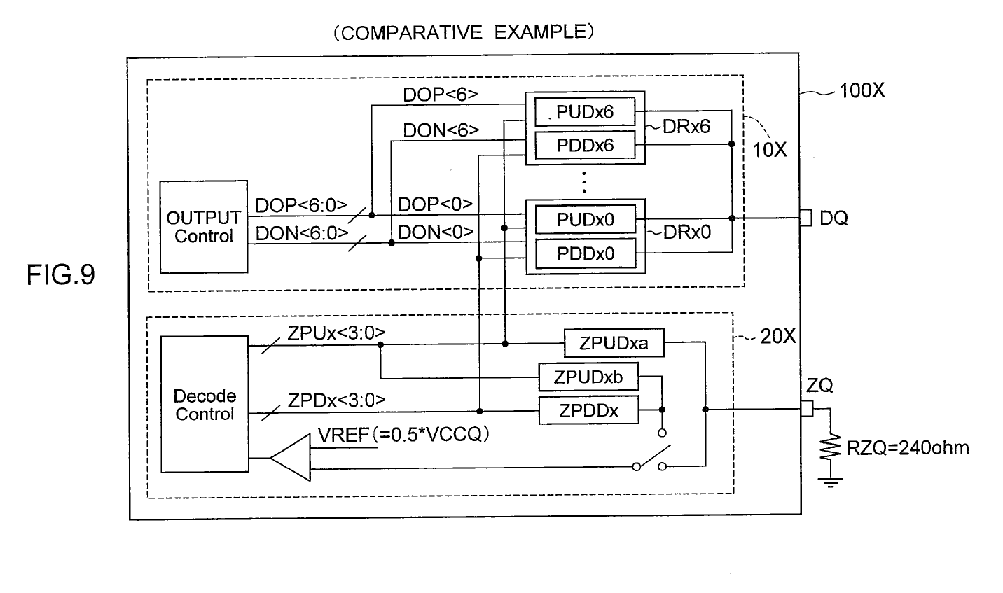

FIG. 9 is a block diagram showing a schematic configuration of a semiconductor device 100X of a comparative example. This semiconductor device 100X is configured as a DDR3-SDRAM.

An output buffer 10X includes seven drivers DRx0 to DRx6. The driver DRx0 includes a pull-up driver PUDx0 and a pull-down driver PDDx0. Other drivers DRx1 to DRx6 are also configured in the same manner.

A calibration circuit 20X adjusts the ON resistance of each of the pull-up drivers PUDx0 to PUDx6 and the pull-down drivers PDDx0 to PDDx6 to a reference resistance value (240Ω) of an external resistor RZQ that is connected to an external resistor terminal ZQ from outside.

At the time of an ODT (On Die Termination) operation, at least one of the drivers DRx0 to DRx6 is selected according to a termination resistance RTT that is set, the pull-up driver and the pull-down driver of the selected driver are turned on, and a signal output terminal DQ is terminated with the termination resistance RTT.

As indicated below, the termination resistance RTT at the time of the ODT operation of the output buffer 10X is normalized to a value which is obtained by dividing the reference resistance value (240Ω) of the external resistor RZQ by a multiple of 2. It is necessary that the output buffer 10X realize these termination resistances RTT.

RTT=120Ω(RZQ/2)

RTT=60Ω(RZQ/4)

RTT=40Ω(RZQ/6)

RTT=30Ω(RZQ/8)

RTT=20Ω(RZQ/12)

It is possible to realize RTT=120Ω (240Ω=RZQ/1) by one driver DRx0.

It is possible to realize RTT=60Ω (120Ω=RZQ/2) by two drivers DRx0 and DRx1.

It is possible to realize RTT=40Ω (80Ω=RZQ/3) by three drivers DRx0 to DRx2.

It is possible to realize RTT=30Ω) (60Ω=RZQ/4) by four drivers DRx0 to DRx3.

It is possible to realize RTT=20Ω (40Ω=RZQ/6) by six drivers DRx0 to DRx5.

In this manner, each setting may be realized by a configuration where the smallest unit is the external resistor RZQ, that is, “drivers DRx0 to DRx5 configured in 240Ω (that is, driver whose ON resistance may be adjusted to 240Ω)”.

In addition, the strength of output of a signal by the output buffer 10X (Driver Strength) is also normalized. This strength is specified by impedance Ron on the signal output terminal DQ of the output buffer 10X, and the setting is as described below. The impedance Ron indicates the impedance on the pull-up side of the output buffer 10X and the impedance on the pull-down side.

Ron=RZQ/6(=40Ω)

Ron=RZQ/7(=34.3Ω)

It is possible to realize Ron=RZQ/6 (=40Ω) by six drivers DRx0 to DRx5.

It is possible to realize Ron=RZQ/7 (=34.3Ω) by seven drivers DRx0 to DRx6.

In this manner, each setting may be realized by a configuration where the smallest unit is the external resistor RZQ, that is, “drivers DRx0 to DRx6 configured in 240 Ω”.

Accordingly, it is sufficient if the output buffer 10X, that satisfies the RTT and the Ron according to the standard for the DDR3-SDRAM, includes seven “drivers DRx0 to DRx6 configured in 240Ω”, as shown in FIG. 9.

On the other hand, there is a standard called Toggle3.0 for a NAND-type non-volatile semiconductor memory device. According to this standard, the termination resistance RTT at the time of the ODT operation of the output buffer is set in the following manner. In this case, the resistance value of the external resistor RZQ is 300 Ω.

RTT=150Ω(RZQ/2)

RTT=100Ω(RZQ/3)

RTT=75Ω (RZQ/4)

RTT=50Ω (RZQ/6)

The following is true in the case where the settings mentioned above are to be realized by using drivers configured in 300 Ω.

It is possible to realize RTT=150Ω by one “driver configured in 300 Ω”.

It is not possible to realize RTT=100Ω because this requires ⅔ “drivers configured in 300 Ω”.

It is possible to realize RTT=75Ω by two “drivers configured in 300 Ω”.

It is possible to realize RTT=50Ω by three “drivers configured in 300 Ω”.

As described, RTT=100Ω cannot be realized by only “driver(s) configured in 300 Ω”.

That is, termination resistances RTT (150, 75, 50Ω) which are values obtained by dividing the reference resistance value (300Ω) by a multiple of two may be realized, but a termination resistance (100Ω) which is not a value that is obtained by dividing the reference resistance value by a multiple of two cannot be realized.

Moreover, the impedance Ron of the output buffer is also normalized as below.

Ron=50 Ω

Ron=35Ω

Ron=25 Ω

It is possible to realize Ron=50 Ω by six “drivers configured in 300 Ω”.

It is not possible to realize Ron=35Ω because this requires 8.5 “drivers configured in 300 Ω”.

It is possible to realize Ron=25 Ω by twelve “drivers configured in 300 Ω”.

As described, Ron=35 Ω cannot be realized by only “driver(s) configured in 300 Ω”.

That is, impedance Ron (50, 25Ω) which are values obtained by dividing the reference resistance value (300Ω) by an integer of two or more may be realized, but impedance Ron (35Ω) which is not a value that is obtained by dividing the reference resistance value by an integer of two or more cannot be realized.

That is, RTT and Ron according to the standard for the NAND-type non-volatile semiconductor memory device cannot be realized by the same configuration as that of FIG. 9.

The present inventor has achieved the present invention based on the unique knowledge described above.

Hereinafter, embodiments of the present invention will be described with reference to the drawings. The embodiments do not limit the present invention.

### First Embodiment

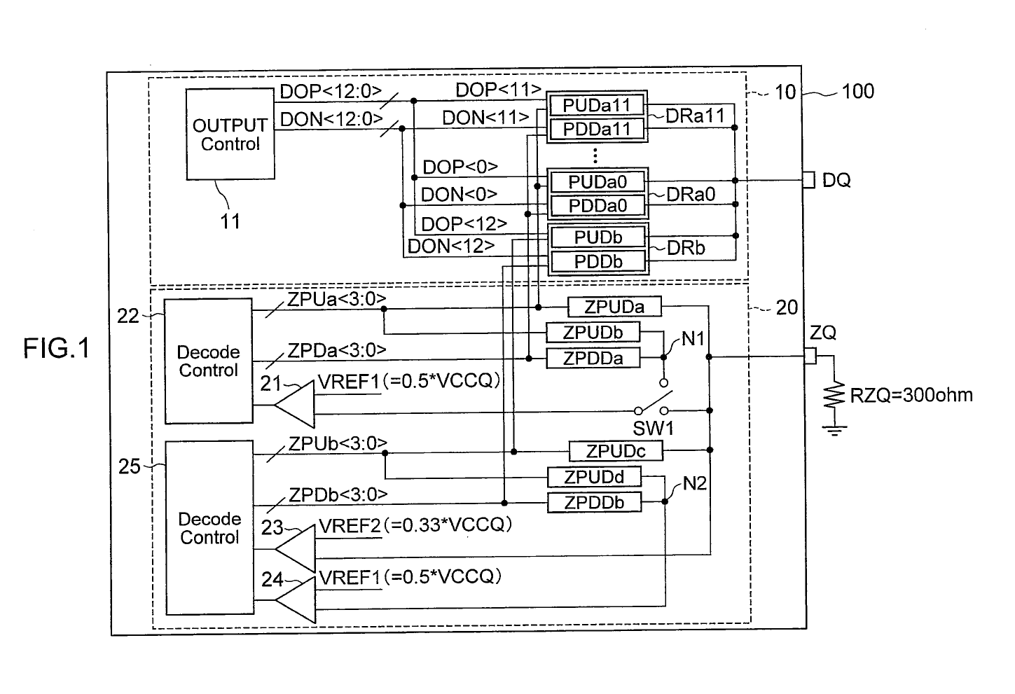

FIG. 1 is a block diagram showing a schematic configuration of a semiconductor device 100 according to a first embodiment. As shown in FIG. 1, the semiconductor device 100 includes an output buffer 10, a calibration circuit 20, a signal output terminal DQ, and an external resistor terminal ZQ.

The semiconductor device 100 is configured as a NAND-type non-volatile semiconductor memory device, for example. Elements other than those shown in the drawing are not directly related to the present embodiment, and illustration and description thereof are omitted. Also, one output buffer 10 and one signal output terminal DQ are illustrated and described, but the same number of output buffers and signal output terminals as the number of bits of a data signal to be output by the semiconductor device 100 are provided.

An external resistor RZQ having a predetermined reference resistance value is connected to the external resistor terminal ZQ. In the present embodiment, the reference resistance value is 300Ω, but this is not restrictive.

At the time of a data output operation, the output buffer 10 outputs a data signal according to output data read out from a memory core (not shown) to the signal output terminal DQ. At the time of a termination (ODT) operation, the output buffer 10 does not output a data signal, and functions as a termination resistance RTT for terminating the signal output terminal DQ.

The output buffer 10 includes twelve first drivers DRa0 to DRa11, one second driver DRb, and an output control circuit 11.

Each of the first drivers DRa0 to DRa11 includes corresponding first pull-up drivers PUDa0 to PUDa11, and corresponding first pull-down drivers PDDa0 to PDDa11.

The first pull-up drivers PUDa0 to PUDa11 have the same configuration.

The first pull-down drivers PDDa0 to PDDa11 have the same configuration.

Additionally, the term “same” in the present specification is not limited strictly to its original meaning, and may be interpreted to include a range where a similar function may be expected.

Each of the first pull-up drivers PUDa0 to PUDa11 may pull up the voltage of the signal output terminal DQ according to corresponding pull-up signals DOP<0> to DOP<11>, and may have the ON resistance at the time of pulling up adjusted to the reference resistance value. In the following, pulling up of the voltage by a pull-up driver will be referred to also as turning on of the pull-up driver.

Each of the first pull-down drivers PDDa0 to PDDa11 may pull down the voltage of the signal output terminal DQ according to corresponding pull-down signals DON<0> to DON<11>, and may have the ON resistance at the time of pulling down adjusted to the reference resistance value. In the following, pulling down of the voltage by a pull-down driver will be referred to also as turning on of the pull-down driver.

The second driver DRb includes a second pull-up driver PUDb, and a second pull-down driver PDDb.

The second pull-up driver PUDb may pull up the voltage of the signal output terminal DQ according to a corresponding pull-up signal DOP<12>, and may have the ON resistance at the time of pulling up adjusted to n times (n is an integer of two or more) the reference resistance value. In the following, n is two.

The second pull-down driver PDDb may pull down the voltage of the signal output terminal DQ according to a corresponding pull-down signal DON<12>, and may have the ON resistance at the time of pulling down adjusted to n times the reference resistance value.

The output control circuit 11 outputs a pull-up signal DOP<12:0> and a pull-down signal DON<12:0>.

The calibration circuit 20 adjusts, at the time of calibration, by using the external resistor RZQ, the ON resistance of each of the first pull-up drivers PUDa0 to PUDa11 and the first pull-down drivers PDDa0 to PDDa11 to the reference resistance value, and adjusts the ON resistance of each of the second pull-up driver PUDb and the second pull-down driver PDDb to n times the reference resistance value.

The calibration circuit 20 outputs a first pull-up calibration signal ZPUa<3:0>, a first pull-down calibration signal ZPDa<3:0>, a second pull-up calibration signal ZPUb<3:0>, and a second pull-down calibration signal ZPDb<3:0> to the output buffer 10.

The ON resistance of each of the first pull-up drivers PUDa0 to PUDa11 is adjusted by the first pull-up calibration signal ZPUa<3:0>.

The ON resistance of each of the first pull-down drivers PDDa0 to PDDa11 is adjusted by the first pull-down calibration signal ZPDa<3:0>.

The ON resistance of the second pull-up driver PUDb is adjusted by the second pull-up calibration signal ZPUb<3:0>.

The ON resistance of the second pull-down driver PDDb is adjusted by the second pull-down calibration signal ZPDb<3:0>. The calibration circuit 20 includes a first pull-up driver for adjustment ZPUDa, a second pull-up driver for adjustment ZPUDb, a third pull-up driver for adjustment ZPUDc, a fourth pull-up driver for adjustment ZPUDd, a first pull-down driver for adjustment ZPDDa, a second pull-down driver for adjustment ZPDDb, a comparator circuit 21, a first control circuit (Decode Control) 22, comparator circuits 23 and 24, a second control circuit (Decode Control) 25, and a switch SW1.

The first pull-up driver for adjustment ZPUDa pulls up the voltage of the external resistor terminal ZQ, and has the ON resistance adjusted by the first pull-up calibration signal ZPUa<3:0>. The first pull-up driver for adjustment ZPUDa has the same configuration as the first pull-up driver PUDa0.

The second pull-up driver for adjustment ZPUDb pulls up the voltage of a first node N1, and has the ON resistance adjusted by the first pull-up calibration signal ZPUa<3:0>. The second pull-up driver for adjustment ZPUDb has the same configuration as the first pull-up driver PUDa0.

The first pull-down driver for adjustment ZPDDa pulls down the voltage of the first node N1, and has the ON resistance adjusted by the first pull-down calibration signal ZPDa<3:0>. The first pull-down driver for adjustment ZPDDa has the same configuration as the first pull-down driver PDDa0.

The switch SW1 supplies the voltage of the external resistor terminal ZQ or the voltage of the first node N1 to the comparator circuit 21.

The comparator circuit 21 compares the voltage of the external resistor terminal ZQ or the voltage of the first node N1, which has been supplied, with a first reference voltage VREF1. The first reference voltage VREF1 is 0.5VCCQ. The VCCQ indicates the voltage of a power supply VCCQ.

The first control circuit 22 determines the first pull-up calibration signal ZPUa<3:0> according to the comparison result of the comparator circuit 21 in such a way that the voltage of the external resistor terminal ZQ comes closer to the first reference voltage VREF1. The ON resistance of each of the first and second pull-up drivers for adjustment ZPUDa and ZPUDb thereby becomes approximately equal to the reference resistance value. Accordingly, the ON resistance of each of the first pull-up drivers PUDa0 to PUDa11 also becomes approximately equal to the reference resistance value. The first control circuit 22 then determines the first pull-down calibration signal ZPDa<3:0> in such a way that the voltage of the first node N1 comes closer to the first reference voltage VREF1. The ON resistance of the first pull-down driver for adjustment ZPDD thereby becomes approximately equal to the reference resistance value. Accordingly, the ON resistance of each of the first pull-down drivers PDDa0 to PDDa11 also becomes approximately equal to the reference resistance value.

The first control circuit 22 stores the first pull-up calibration signal ZPUa<3:0> and the first pull-down calibration signal ZPDa<3:0> which have been determined.

The third pull-up driver for adjustment ZPUDc pulls up the voltage of the external resistor terminal ZQ, and has the ON resistance adjusted by the second pull-up calibration signal ZPUb<3:0>. The third pull-up driver for adjustment ZPUDc has the same configuration as the second pull-up driver PUDb.

The fourth pull-up driver for adjustment ZPUDd pulls up the voltage of a second node N2, and has the ON resistance adjusted by the second pull-up calibration signal ZPUb<3:0>. The fourth pull-up driver for adjustment ZPUDd has the same configuration as the second pull-up driver PUDb.

The second pull-down driver for adjustment ZPDDb pulls down the voltage of the second node N2, and has the ON resistance adjusted by the second pull-down calibration signal ZPDb<3:0>. The second pull-down driver for adjustment ZPDDb has the same configuration as the second pull-down driver PDDb.

The comparator circuit 23 compares the voltage of the external resistor terminal ZQ and a second reference voltage VREF2. The second reference voltage VREF2 is a voltage corresponding to the n, and is 0.33VCCQ in this case.

The comparator circuit 24 compares the voltage of the second node N2 and the first reference voltage VREF1.

The second control circuit 25 determines the second pull-up calibration signal ZPUb<3:0> in such a way that the voltage of the external resistor terminal ZQ comes closer to the second reference voltage VREF2. The ON resistance of each of the third and fourth pull-up drivers for adjustment ZPUDc and ZPUDd thereby becomes about n times the reference resistance value. Accordingly, the ON resistance of the second pull-up driver PUDb also becomes about n times the reference resistance value.

The second control circuit 25 then determines the second pull-down calibration signal ZPDb<3:0> in such a way that the voltage of the second node N2 comes closer to the first reference voltage VREF1. The ON resistance of the second pull-down driver for adjustment ZPDDb thereby becomes about n times the reference resistance value. Accordingly, the ON resistance of the second pull-down driver PDDb also becomes about n times the reference resistance value.

The second control circuit 25 stores the second pull-up calibration signal ZPUb<3:0> and the second pull-down calibration signal ZPDb<3:0> which have been determined.

The second control circuit 25 controls the third pull-up driver for adjustment ZPUDc to off while the first control circuit 22 is performing calibration, and the first control circuit 22 controls the first pull-up driver for adjustment ZPUDa to off while the second control circuit 25 is performing calibration.

That is, the calibration circuit 20 performs calibration by the second control circuit 25 after calibration by the first control circuit 22 has ended. The order of calibration may be reversed.

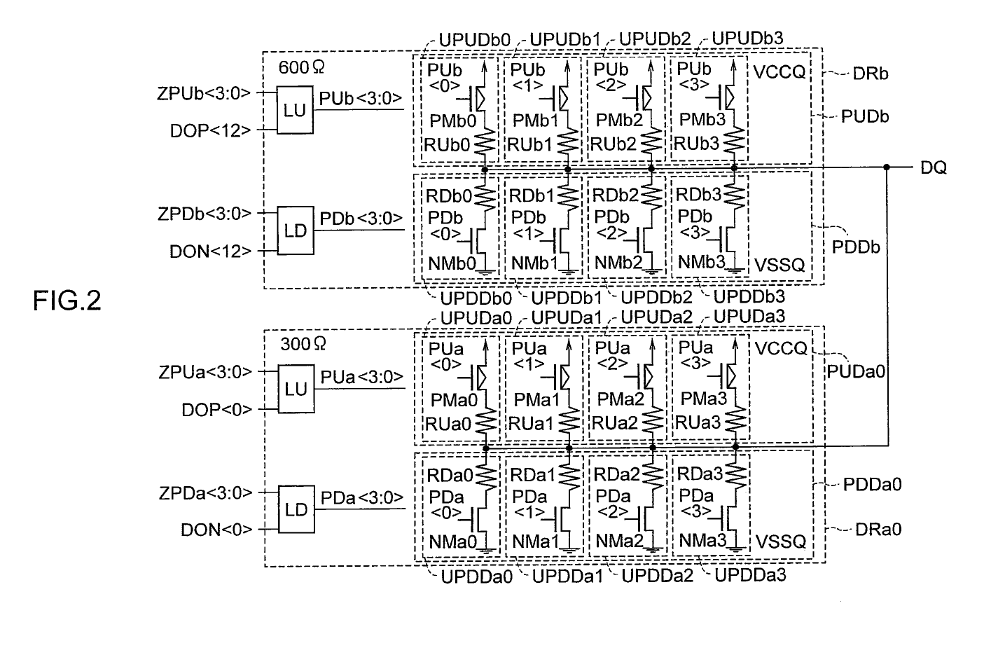

FIG. 2 is a circuit diagram of the drivers DRa0 and DRb of the semiconductor device 100 of FIG. 1. The first drivers DRa0 to DRa11 have the same configuration, and thus, illustration and description of the rest of the drivers will be omitted.

### [Configuration of First Driver DRa0]

The first driver DRa0 includes, in addition to the first pull-up driver PUDa0 and the first pull-down driver PDDa0, logic circuits LU and LD.

The first pull-up driver PUDa0 includes m (m is an integer of two or more) first unit pull-up drivers UPUDa0 to UPUDa3, each of which pulling up the voltage of the signal output terminal DQ. Here, m is four.

The first pull-down driver PDDa0 includes m first unit pull-down drivers UPDDa0 to UPDDa3, each of which pulling down the voltage of the signal output terminal DQ.

The logic circuit LU outputs a first pull-up calibration signal ZPUa<3:0> as an operation signal PUa<3:0> when a corresponding pull-up signal DOP<0> is activated. At least one of the first unit pull-up drivers UPUDa0 to UPUDa3 is thereby turned on according to the first pull-up calibration signal ZPUa<3:0>. At this time, the ON resistance of the first pull-up driver PUDa0 is the reference resistance value.

The logic circuit LU outputs an operation signal PUa<3:0> when a corresponding pull-up signal DOP<0> is not activated, so as to turn off the first unit pull-up drivers UPUDa0 to UPUDa3.

The logic circuit LD outputs a first pull-down calibration signal ZPDa<3:0> as an operation signal PDa<3:0> when a corresponding pull-down signal DON<0> is activated. At least one of the first unit pull-down drivers UPDDa0 to UPDDa3 is thereby turned on according to the first pull-down calibration signal ZPDa<3:0>. At this time, the ON resistance of the first pull-down driver PDDa0 is the reference resistance value.

The logic circuit LD outputs an operation signal PDa<3:0> when a corresponding pull-down signal DON<0> is not activated, so as to turn off the first unit pull-down drivers UPDDa0 to UPDDa3.

Each first unit pull-up driver UPUDai (hereinafter, i is assumed to be between zero and three) includes a first PMOS transistor PMai and a first pull-up resistor RUai that are connected in series between the power supply VCCQ and the signal output terminal DQ. First PMOS transistors PMa0 to PMa3 are arranged on the side of the power supply VCCQ.

A corresponding operation signal PUa<i> is supplied to the gate of each first PMOS transistor PMai.

The sizes of the first PMOS transistors PMa0 to PMa3 may be any sizes, and they may be set such that the ratio of the ON resistances of the PMa0, PMa1, PMa2, and PMa3 is 1:2:4:8, for example.

The resistance values of first pull-up resistors RUa0 to RUa3 may be any resistance values, and may be set to RUa0:RUa1:RUa2:RUa3=1:2:4:8, for example.

Each first unit pull-down driver UPDDai includes a first NMOS transistor NMai and a first pull-down resistor RDai that are connected in series between the signal Output terminal DQ and a ground VSSQ. First NMOS transistors NMa0 to NMa3 are arranged on the side of the ground VSSQ.

A corresponding operation signal PDa<i> is supplied to the gate of each first NMOS transistor NMai.

The sizes of the first NMOS transistors NMa0 to NMa3 are set in the same manner as the sizes of the first PMOS transistors PMa0 to PMa3. The resistance values of the first pull-down resistors RDa0 to RDa3 are set in the same manner as the resistance values of the first pull-up resistors RUa0 to RUa3.

### [Configuration of Second Driver DRb]

The second driver DRb includes, in addition to the second pull-up driver PUDb and the second pull-down driver PDDb, logic circuits LU and LD.

The second pull-up driver PUDb includes m second unit pull-up drivers UPUDb0 to UPUDb3, each of which pulling up the voltage of the signal output terminal DQ.

The second pull-down driver PDDb includes m second unit pull-down drivers UPDDb0 to UPDDb3, each of which pulling down the voltage of the signal output terminal DQ.

The ON resistance of each second unit pull-up driver UPUDbi is n times the ON resistance of the corresponding first unit pull-up driver UPUDai.

The ON resistance of each second unit pull-down driver UPDDbi is n times the ON resistance of the corresponding first unit pull-down driver UPDDai.

The operations of the logic circuits LU and LD of the second driver DRb are the same as the operations of the logic circuit LU and LD of the first driver DRa0. That is, at least one of the second unit pull-up drivers UPUDb0 to UPUDb3 is turned on when a corresponding pull-up signal DOP<12> is activated, according to the second pull-up calibration signal ZPUb<3:0>.

At least one of the second unit pull-down drivers UPDDb0 to UPDDb3 is turned on when a corresponding pull-down signal DON<12> is activated, according to the second pull-down calibration signal ZPDb<3:0>.

Each second unit pull-up driver UPUDbi includes a second PMOS transistor PMbi and a second pull-up resistor RUbi that are connected in series between the power supply VCCQ and the signal output terminal DQ. Second PMOS transistors PMbO to PMb3 are arranged on the side of the power supply VCCQ.

A corresponding operation signal PUb<i> is supplied to the gate of each second PMOS transistors PMbi.

The ON resistance of the second PMOS transistor PMbi of each second unit pull-up driver UPUDbi is n times the ON resistance of the first PMOS transistor PMai of the corresponding first unit pull-up driver UPUDai.

The resistance value of the second pull-up resistor RUbi of each second unit pull-up driver UPUDbi is n times the resistance value of the first pull-up resistor RUai of the corresponding first unit pull-up driver UPUDai.

Each second unit pull-down driver UPDDbi includes a second NMOS transistor NMbi and a second pull-down resistor RDbi that are connected in series between the signal output terminal DQ and the ground VSSQ. Second NMOS transistors NMb0 to NMb3 are arranged on the side of the ground VSSQ.

A corresponding operation signal PDb<i> is supplied to the gate of the each second NMOS transistor NMbi.

The ON resistance of the second NMOS transistor NMbi of each second unit pull-down driver UPDDbi is n times the ON resistance of the first NOS transistor NMai of the corresponding first unit pull-down driver UPDDai.

The resistance value of the second pull-down resistor RDbi of each second unit pull-down driver UPDDbi is n times the resistance value of the first pull-down resistor RDai of the corresponding first unit pull-down driver UPDDai.

Next, an operation of the semiconductor device 100 will be described.

### [Calibration Operation]

Calibration is performed to correct variations in the ON resistances of the first and second pull-up drivers PUDa0 to PUDa11, PUDb and the like due to the process conditions at the time of manufacturing, and also, to correct a change in the ON resistance caused by a change in the power supply voltage or the ambient temperature. Accordingly, calibration is desirably performed on a regular basis also during an operation, instead of being performed once at the time of initial setting such as at the time of turning on the power or at the time of resetting.

A data output operation or a termination operation is performed after the calibration is performed at least once.

### [Data Output Operation]

At the time of a data output operation, the output control circuit 11 selects a driver to be operated among the first drivers DRa0 to DRa11 and the second driver DRb, according to the impedance Ron that is set. Then, the output control circuit 11 outputs a pull-up signal DOP<12:0> and a pull-down signal DON<12:0> according to output data which has been read out, so as to cause a driver to be operated to perform pulling up or pulling down.

It is possible to realize impedance Ron=50Ω by operating six first drivers DRa0 to DRa5 configured in 300Ω. That is, at the time of pulling up, impedance Ron=300/6=50Ω is achieved by the first pull-up drivers PUDa0 to PUDa5 being turned on. At the time of pulling down, impedance Ron=300/6=50Ω is achieved by the first pull-down drivers PDDa0 to PDDa5 being turned on.

It is possible to realize impedance Ron=35Ω by operating eight first drivers DRa0 to DRa7 configured in 300Ω and one second driver DRb configured in 600 Ω.

It is possible to realize impedance Ron=25Ω by operating twelve first drivers DRa0 to DRa11 configured in 300 Ω.

Additionally, any driver among the first drivers DRa0 to DRa11 may be caused to operate.

In this manner, impedance Ron=35Ω that cannot be realized by the configuration of the comparative example may be realized.

### [Termination Operation]

A termination operation is performed in a case where the signal output terminal DQ of the semiconductor device 100 and a signal output terminal of another semiconductor device having the same configuration as the semiconductor device 100 are connected, and the semiconductor device 100 is not performing the data output operation and the other semiconductor device is performing the data output operation, for example.

At the time of the termination operation, the output control circuit 11 selects the driver to be operated among the first drivers DRa0 to DRa11 and the second driver DRb according to the termination resistance RTT that is set. At this time, the output control circuit 11 outputs a pull-up signal DOP<12:0> and a pull-down signal DON<12:0> so as to turn on both the pull-up driver and the pull-down driver of the driver to be operated.

The signal output terminal DQ may thereby terminated with the termination resistance RTT, and reflection of a signal at the signal output terminal DQ may be suppressed. At the time of the termination operation, the voltage of the signal output terminal DQ is about VCCQ/2.

It is possible to realize termination resistance RTT=150Ω by operating one first driver DRa0 configured in 300Ω. That is, termination resistance RTT=300/2=150Ω is achieved by both the first pull-up driver PUDa0 and the first pull-down driver PDDa0 of the first driver DRa0 being turned on.

It is possible to realize termination resistance RTT=100Ω by operating one first driver DRa0 configured in 300Ω and one second driver DRb configured in 600 Ω.

It is possible to realize termination resistance RTT=75Ω by operating two first drivers DRa0 and DRa1 configured in 300 Ω.

It is possible to realize termination resistance RTT=50Ω by operating three first drivers DRa0 to DRa2 configured in 300 Ω.

In this manner, RTT=100Ω that cannot be realized by the configuration of the comparative example may be realized.

As described above, according to the first embodiment, the ON resistance of the second pull-up driver PUDb may be adjusted to n times the reference resistance value (that is, the ON resistance of the first pull-up driver PUDa0), and thus, when the first and second pull-up drivers PUDa0 and PUDb are turned on, the impedance Ron of the output buffer 10 on the signal output terminal ZQ may be set to n/(1+n) times the reference resistance value. In the same manner, when the first and second pull-down drivers PDDa0 and PDDb are turned on, the impedance Ron may be set to n/(1+n) times the reference resistance value.

Accordingly, impedance Ron which is not a value obtained by dividing the reference resistance value (300Ω) of the external resistor RZQ by an integer of two or more may be realized.

Also, when the first and second pull-up drivers PUDa0 and PUDb, and the first and second pull-down drivers PDDa0 and PDDb are turned on, the termination resistance RTT of the signal output terminal ZQ may be set to n/2(1+n) times the reference resistance value.

Accordingly, a termination resistance RTT which is not a value obtained by dividing the reference resistance value (300Ω) by a multiple of two may be realized.

That is, a termination resistance RTT and impedance Ron that cannot be realized by simply providing a plurality of pull-up drivers and pull-down drivers whose ON resistances may be adjusted to the reference resistance value, as in the case of the comparative example, may be realized.

In addition, since calibration of the first drivers DRa0 to DRa11 and calibration of the second driver DRb are performed separately, the calibration accuracy is high.

### Second Embodiment

A second embodiment is different from the first embodiment in that calibration of the first drivers DRa0 to DRa11 and calibration of the second driver DRb are performed at the same time.

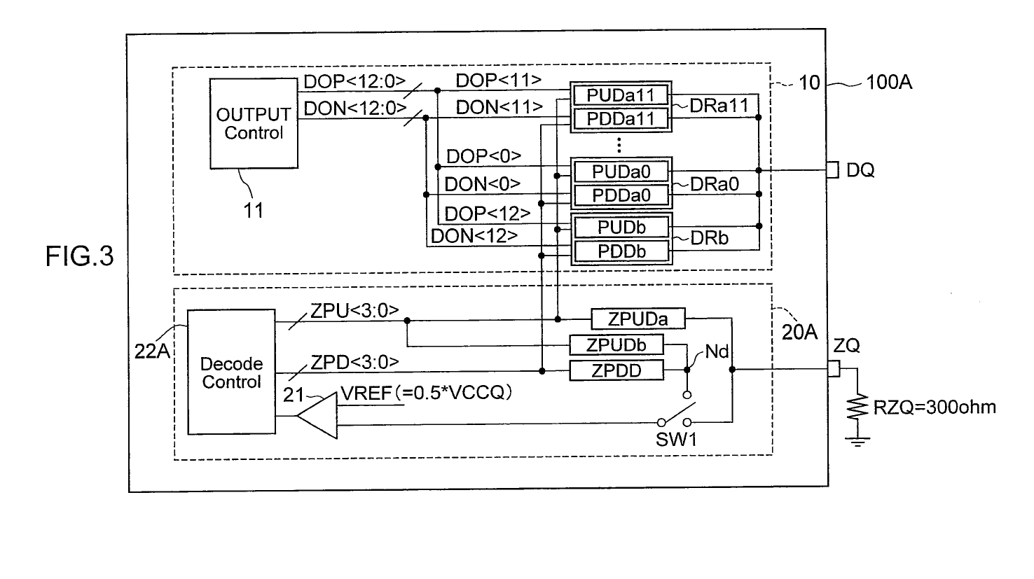

FIG. 3 is a block diagram showing a schematic configuration of a semiconductor device 100A according to the second embodiment. In FIG. 3, the same structural elements as in FIG. 1 are denoted with the same reference signs, and differences will be mainly described in the following.

A calibration circuit 20A outputs a pull-up calibration signal ZPU<3:0> and a pull-down calibration signal ZPD<3:0> to the output buffer 10.

The ON resistances of the first pull-up drivers PUDa0 to PUDa11 and the second pull-up driver PUDb are adjusted by the pull-up calibration signal ZPU<3:0>.

The ON resistances of the first pull-down drivers PDDa0 to PDDa11 and the second pull-down driver PDDb are adjusted by the pull-down calibration signal ZPD<3:0>.

The calibration circuit 20A includes a first pull-up driver for adjustment ZPUDa, a second pull-up driver for adjustment ZPUDb, a pull-down driver for adjustment ZPDD, a comparator circuit 21, and a control circuit 22A.

The first pull-up driver for adjustment ZPUDa pulls up the voltage of the external resistor terminal ZQ, and has the ON resistance adjusted by the pull-up calibration signal ZPU<3:0>. The first pull-up driver for adjustment ZPUDa has the same configuration as the first pull-up driver PUDa0.

The second pull-up driver for adjustment ZPUDb pulls up the voltage of a detection node Nd, and has the ON resistance adjusted by the pull-up calibration signal ZPU<3:0>. The second pull-up driver for adjustment ZPUDb has the same configuration as the first pull-up driver PUDa0.

The pull-down driver for adjustment ZPDD pulls down the voltage of the detection node Nd, and has the ON resistance adjusted by the pull-down calibration signal ZPD<3:0>. The pull-down driver for adjustment ZPDD has the same configuration as the first pull-down driver PDDa0.

The control circuit 22A determines the pull-up calibration signal ZPU<3:0> in such a way that the voltage of the external resistor terminal ZQ comes closer to a reference voltage VREF (=0.5VCCQ). The ON resistance of each of the first and second pull-up drivers for adjustment ZPUDa and ZPUDb thereby becomes approximately equal to the reference resistance value.

The control circuit 22A then determines the pull-down calibration signal ZPD<3:0> in such a way that the voltage of the detection node Nd comes closer to the reference voltage VREF. The ON resistance of the pull-down driver for adjustment ZPDD thereby becomes approximately equal to the reference resistance value.

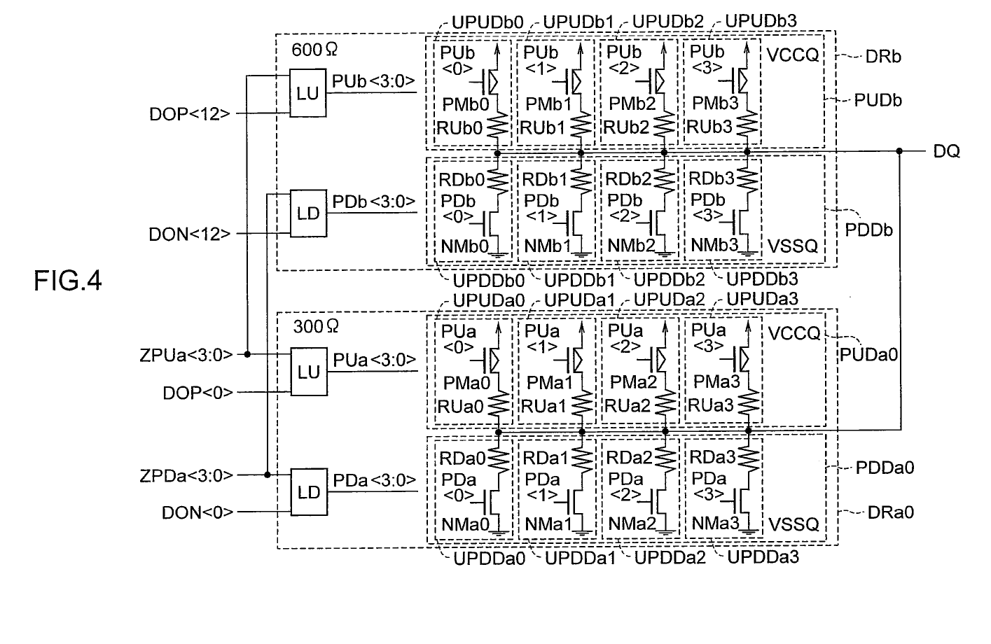

FIG. 4 is a circuit diagram of drivers DRa0 and DRb of the semiconductor device 100A of FIG. 3. In FIG. 4, the same structural elements as in FIG. 2 are denoted with the same reference signs, and differences will be mainly described in the following.

The configurations of the drivers DRa0 and DRb are the same as those in FIG. 2, but that the same pull-up calibration signal ZPU<3:0> and pull-down calibration signal ZPD<3:0> are supplied to the drivers DRa0 and DRb is different from FIG. 2.

That is, at least one of the first unit pull-up drivers UPUDa0 to UPUDa3 and at least one of the second unit pull-up drivers UPUDb0 to UPUDb3 are turned on according to the pull-up calibration signal ZPU<3:0>.

At least one of the first unit pull-down drivers UPDDa0 to UPDDa3 and at least one of the second unit pull-doWn drivers UPDDb0 to UPDDb3 are turned on according to the pull-down calibration signal ZPD<3:0>.

Also, in FIG. 2, the ON resistance of each second unit pull-up driver UPUDbi does not have to be n times the ON resistance of the corresponding first unit pull-up driver UPUDai, but in the second embodiment, n times is desirable. The same can be said for the first and second unit pull-down drivers UPDDa0 to UPDDa3, and UPDDb0 to UPDDb3.

When calibration is performed by the configuration described above and the ON resistance of each of the first pull-up drivers PUDa0 to PUDa11 and the first pull-down drivers PDDa0 to PDDa11 is adjusted to the reference resistance value, the ON resistance of each of the second pull-up driver PUDb and the second pull-down driver PDDb is inevitably adjusted to n times the reference resistance value.

Accordingly, with the second embodiment, the same effect as the first embodiment is achieved, and also, the calibration time is reduced than in the first embodiment. Moreover, the number of wires for the calibration signal and the area of the calibration circuit 20A may be reduced.

That is, according to the first embodiment, calibration of the first drivers DRa0 to DRa11 and calibration of the second driver DRb are performed separately, and thus, the calibration time is longer than in the second embodiment, and the number of wires for the calibration signal and the area of the calibration circuit 20 are increased. To make the calibration time in the first embodiment the same as that in the second embodiment, the calibration accuracy has to be reduced.

### [Other Configuration of Driver]

The second driver DRb of the second embodiment may alternatively be configured in the following manner.

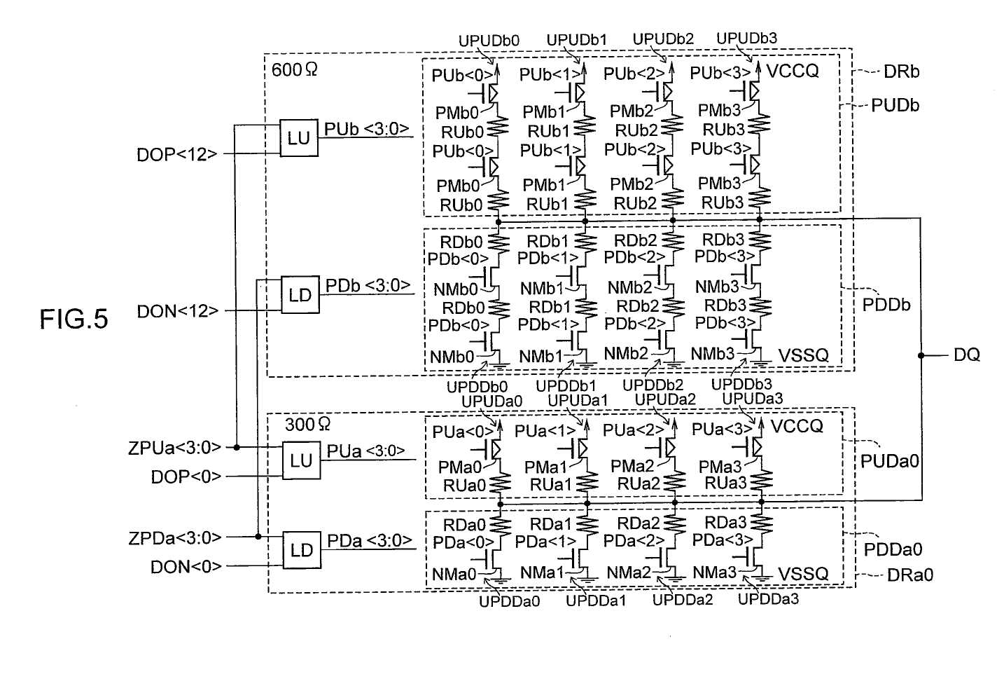

FIG. 5 is another circuit diagram of the drivers DRa0 and DRb of the semiconductor device 100A of FIG. 3. The first driver DRa0 is the same as that in FIG. 4, and a description thereof is omitted.

Each second unit pull-up driver UPUDbi of the second driver DRb includes n second PMOS transistors PMbi and PMbi and n second pull-up resistors RUbi and RUbi that are connected in series between the power supply VCCQ and the signal output terminal DQ.

In each second unit pull-up driver UPUDbi, the second PMOS transistor PMbi, the second pull-up resistor RUbi, the second PMOS transistor PMbi, and the second pull-up resistor RUbi are arranged in this order from the side of the power supply VCCQ.

A corresponding operation signal PUb<i> is supplied to the gate of each of the second PMOS transistors PMbi and PMbi.

The size of each second PMOS transistor PMbi is the same as the size of the corresponding first PMOS transistor PMai.

The resistance value of each second pull-up resistor RUbi is the same as the resistance value of the corresponding first pull-up resistor RUai.

Each second unit pull-down driver UPDDai includes n second NMOS transistors NMbi and NMbi and n second pull-down resistors RDbi and RDbi that are connected in series between the signal output terminal DQ and the ground VSSQ.

In each second unit pull-down driver UPDDai, the second pull-down resistor RDbi, the second NMOS transistor NMbi, the second pull-down resistor RDbi, and the second NMOS transistor NMbi are arranged in this order from the side of the signal output terminal DQ.

A corresponding operation signal PDb<i> is supplied to the gate of each of the second NMOS transistors NMbi and NMbi.

The size of each second NMOS transistor NMbi is the same as the size of the corresponding first NMOS transistor NMai.

The resistance value of each second pull-down resistor RDbi is the same as the resistance value of the corresponding first pull-down resistor RDai.

According to the configuration of FIG. 5, the first and second unit pull-up drivers UPUDa0 to UPUDa3, and UPUDb0 to UPUDb3 are configured by using resistors of the same resistance value and transistors of the same size, and thus, compared to the configuration of FIG. 4, the error regarding the resistance value and the size of the transistor due to the element layout may be reduced. Accordingly, the ON resistance of each second unit pull-up driver UPUDbi may more accurately be made n times the ON resistance of the corresponding first unit pull-up driver UPUDai. The same can be said for the first and second unit pull-down drivers UPDDa0 to UPDDa3, and UPDDb0 to UPDDb3.

Accordingly, the ON resistances of the second pull-up driver PUDb and the second pull-down driver PDDb may more accurately be adjusted to n times the reference resistance value even by performing calibration for adjusting the ON resistance to the reference resistance value just once. That is, the accuracy of the calibration may be increased.

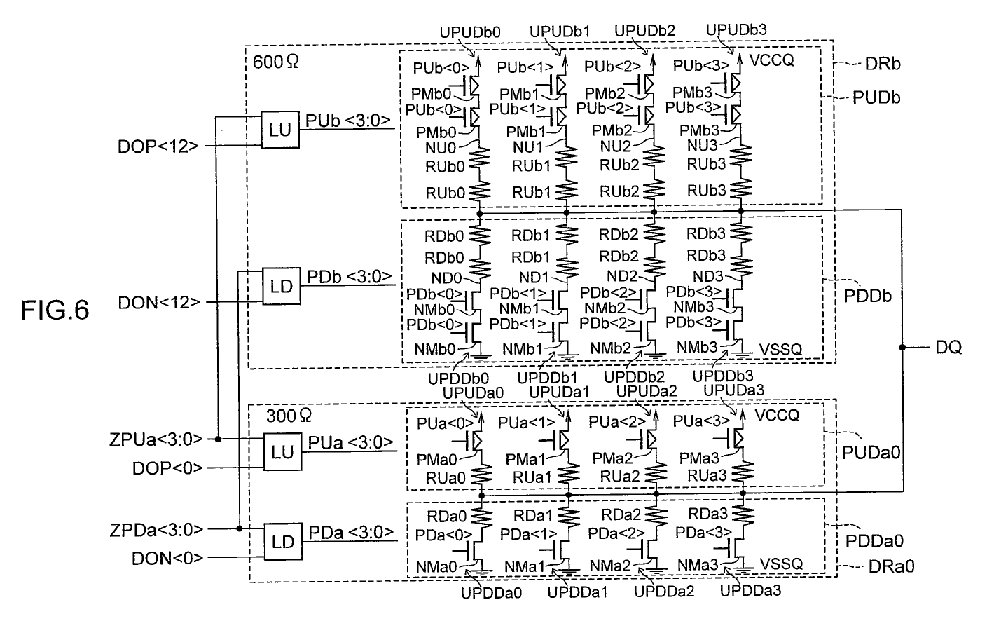

FIG. 6 is further another circuit diagram of the drivers DRa0 and DRb of the semiconductor device of FIG. 3.

In each second unit pull-up driver UPUDbi of the second driver DRb, n second PMOS transistors PMbi and PMbi are connected in series between the power supply VCCQ and a first connection node NUi, and n second pull-up resistors RUbi and RUbi are connected in series between the first connection node NUi and the signal output terminal DQ.

In each second unit pull-down driver UPDDbi, n second pull-down resistors RDbi and RDbi are connected in series between the signal output terminal DQ and a second connection node NDi, and n second NMOS transistors NMbi and NMbi are connected in series between the second connection node NDi and the ground VSSQ.

According to the configuration of FIG. 6, the second PMOS transistors PMbO to PMb3, and PMbO to PMb3 are collectively arranged on the side of the power supply VCCQ, and the second NMOS transistors NMb0 to NMb3, and NMb0 to NMb3 are collectively arranged on the side of the ground VSSQ. Thus, the amount of change in the threshold value caused by the substrate bias effect of these transistors may be reduced than by the configuration of FIG. 5.

Accordingly, the ON resistances of the second pull-up driver PUDb and the second pull-down driver PDDb may be adjusted to n times the reference resistance value more accurately than by the configuration of FIG. 5. That is, the accuracy of calibration may be further increased.

### Third Embodiment

A third embodiment is different from the first and second embodiments in that there are a plurality of drivers having an ON resistance different from the reference resistance value.

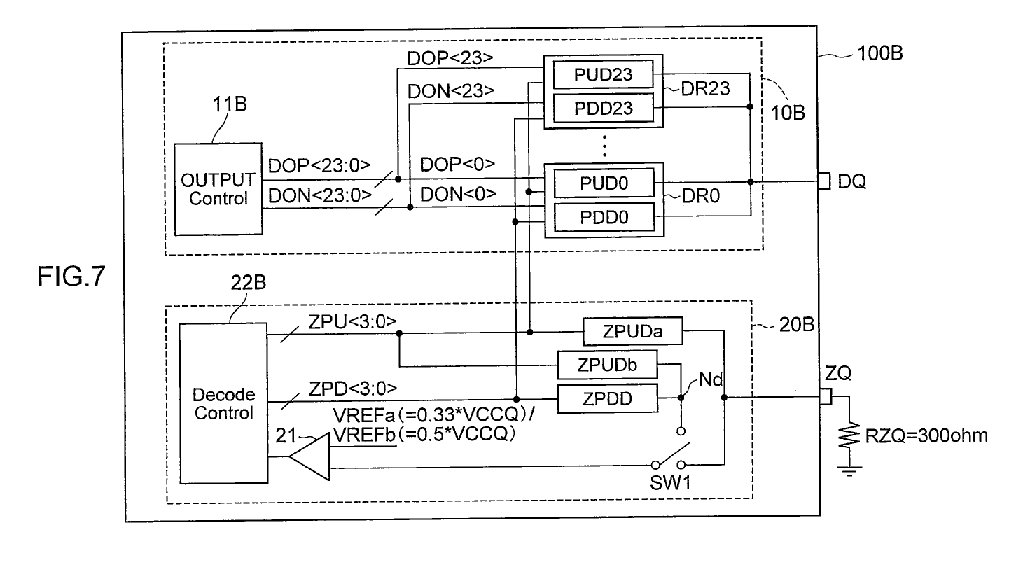

FIG. 7 is a block diagram showing a schematic configuration of a semiconductor device 100B according to the third embodiment. As shown in FIG. 7, the semiconductor device 100B includes an output buffer 10B, and a calibration circuit 20B.

The output buffer 10B includes twenty-four drivers DR0 to DR23, and an output control circuit 11B.

Each of the drivers DR0 to DR23 includes corresponding pull-up drivers PUD0 to PUD23, and corresponding pull-down drivers PDD0 to PDD23.

Each of the pull-up drivers PUD0 to PUD23 pulls up the voltage of the signal output terminal DQ according to a corresponding signal among pull-up signals DOP<0> to DOP<23>, and may have the ON resistance at the time of pulling up adjusted to n (n is an integer of two or more which is not a multiple of three) times the reference resistance value. In the present embodiment, n is two.

The pull-up drivers PUD0 to PUD23 have the same configuration.

Each of the pull-down drivers PDD0 to PDD23 pulls down the voltage of the signal output terminal DQ according to a corresponding signal among pull-down signals DON<0> to DON<23>, and may have the ON resistance at the time of pulling down adjusted to n times the reference resistance value.

The pull-down drivers PDD0 to PDD23 have the same configuration.

The output control circuit 11B outputs the pull-up signals DOP<0> to DOP<23>, and the pull-down signals DON<0> to DON<23>.

At the time of calibration, the calibration circuit 20B adjusts the ON resistance of each of the pull-up drivers PUD0 to PUD23 and the pull-down drivers PDD0 to PDD23 to n times the reference resistance value by using the external resistor RZQ.

The calibration circuit 20B includes a first pull-up driver for adjustment ZPUDa, a second pull-up driver for adjustment ZPUDb, a pull-down driver for adjustment ZPDD, a comparator circuit 21, a control circuit 22B, and a switch SW1.

The first pull-up driver for adjustment ZPUDa pulls up the voltage of the external resistor terminal ZQ, and has the ON resistance adjusted by the pull-up calibration signal ZPU<3:0>. The first pull-up driver for adjustment ZPUDa has the same configuration as the pull-up driver PUD0.

The second pull-up driver for adjustment ZPUDb pulls up the voltage of the detection node Nd, and has the ON resistance adjusted by the pull-up calibration signal ZPU<3:0>. The second pull-up driver for adjustment ZPUDb has the same configuration as the pull-up driver PUD0.

The pull-down driver for adjustment ZPDD pulls down the voltage of the detection node Nd, and has the ON resistance adjusted by the pull-down calibration signal ZPD<3:0>. The pull-down driver for adjustment ZPDD has the same configuration as the pull-down driver PDD0.

The switch SW1 supplies the voltage of the external resistor terminal ZQ or of the detection node Nd to the comparator circuit 21.

The comparator circuit 21 compares the voltage of the external resistor terminal ZQ and a first reference voltage VREFa (=0.33VCCQ) corresponding to the n, and compares the voltage of the detection node Nd and a second reference voltage VREFb (=0.5VCCQ).

The control circuit 22B determines the pull-up calibration signal ZPU<3:0> in such a way that the voltage of the external resistor terminal ZQ comes closer to the first reference voltage VREFa. The ON resistance of each of the first and second pull-up drivers for adjustment ZPUDa and ZPUDb thereby becomes about n times the reference resistance value.

The control circuit 22B then determines the pull-down calibration signal ZPD<3:0> in such a way that the voltage of the detection node Nd comes closer to the second reference voltage VREFb. The ON resistance of the pull-down driver for adjustment ZPDD thereby becomes about n times the reference resistance value.

The ON resistances of the pull-up drivers PUD0 to PUD23 are adjusted by the pull-up calibration signal ZPU<3:0>.

The ON resistances of the pull-down drivers PDD0 to PDD23 are adjusted by the pull-down calibration signal ZPD<3:0>.

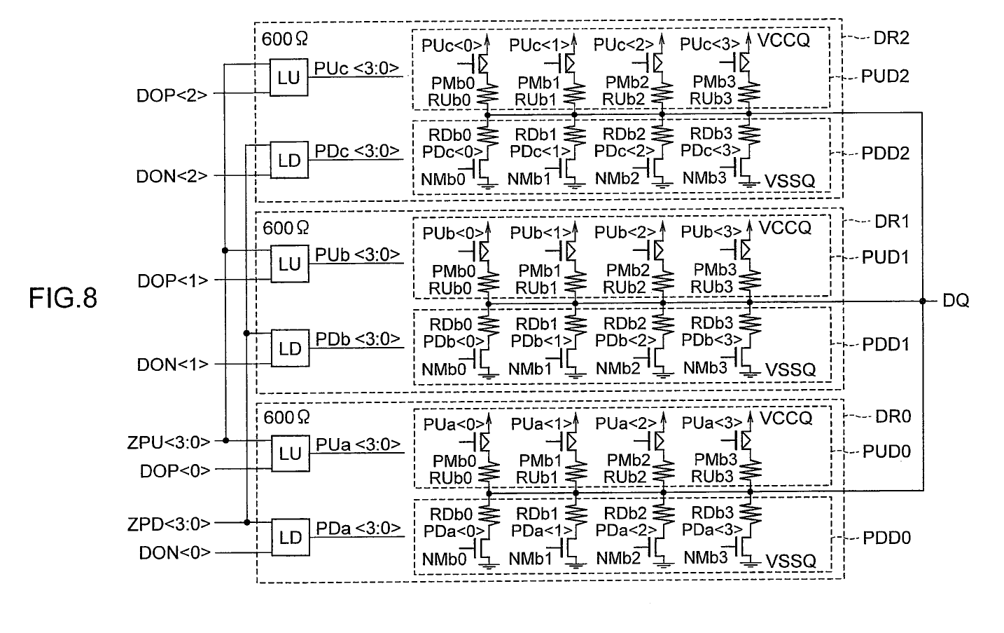

FIG. 8 is a circuit diagram of the drivers DR0 to DR2 of the semiconductor device of FIG. 7. The drivers DR0 to DR2 each have the same configuration as the second driver DRb of the first embodiment, and a detailed description thereof is omitted. That is, the pull-up drivers PUD0 to PUD2 each have the same configuration as the pull-up driver PUDb of the first embodiment, and the pull-down drivers PDD0 to PDD2 each have the same configuration as the pull-down driver PDDb of the first embodiment.

The semiconductor device 100B operates in the following manner at the time of a data output operation.

It is possible to realize impedance Ron=50Ω by operating twelve drivers DR0 to DR11.

It is possible to realize impedance Ron=35Ω by operating seventeen drivers DR0 to DR16.

It is possible to realize impedance Ron=25Ω by operating twenty-four drivers DR0 to DR23.

The semiconductor device 100B operates in the following manner at the time of a termination operation.

It is possible to realize a termination resistance RTT=150Ω by operating two drivers DR0 and DR1.

It is possible to realize a termination resistance RTT=100Ω by operating three drivers DR0 to DR2.

It is possible to realize a termination resistance RTT=75Ω by operating four drivers DR0 to DR3.

It is possible to realize a termination resistance RTT=50Ω by operating six drivers DR0 to DRS.

As described above, according to the third embodiment, the ON resistance of each of the pull-up drivers PUD0 to PUD23 may be adjusted to n times the reference resistance value, and thus, when three pull-up drivers PUD0 to PUD2 are turned on, for example, the impedance Ron may be set to n/3 times the reference resistance value. In the same manner, when three pull-down drivers PDD0 to PDD2 are turned on, the impedance Ron may be set to n/3 times the reference resistance value.

Accordingly, impedance Ron which is not a value that is obtained by dividing the reference resistance value (300Ω) of the external resistor RZQ by an integer of two or more may be realized.

Also, when three pull-up drivers PUD0 to PUD2 and three pull-down drivers PDD0 to PDD2 are turned on, the termination resistance RTT may be set to n/6 times the reference resistance value.

Accordingly, a termination resistance RTT which is not a value that is obtained by dividing the reference resistance value (300Ω) by a multiple of two may be realized.

That is, a termination resistance RTT and impedance Ron that cannot be realized by simply providing a plurality of pull-up drivers and pull-down drivers whose ON resistances may be adjusted to the reference resistance value, as in the case of the comparative example, may be realized.

Additionally, the semiconductor devices 100, 100A, and 1008 may be configured as memory devices such as an SDRAM, for example. In addition, the semiconductor devices 100, 100A, and 100B do not have to be memory devices.

Furthermore, the number of drivers DRa0 to DRa11, DRb, and DR0 to DR23 is not limited to the examples described above, and may be changed as appropriate according to the impedance Ron and the termination resistance RTT to be set.

Moreover, the number of bits of a calibration signal such as the first and second pull-up calibration signals ZPUa<3:0> and ZPUb<3:0>, and the first and second pull-down calibration signals ZPDa<3:0> and ZPDb<3:0> is not limited to the examples described above, and may be changed as appropriate according to the calibration accuracy and the calibration time. In the case of changing the number of bits of a calibration signal, the number (m) of the first unit pull-up drivers UPUDa0 to UPUDa3, the first unit pull-down drivers UPDDa0 to UPDDa3, and the like, may be changed according to the number of bits.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fail within the scope and spirit of the inventions.

1. A semiconductor device comprising:
a first pull-up driver configured to pull up a voltage of a signal output terminal according to a corresponding pull-up signal, whose ON resistance at a time of pulling up is capable of being adjusted to a predetermined reference resistance value;
a first pull-down driver configured to pull down the voltage of the signal output terminal according to a corresponding pull-down signal, whose ON resistance at a time of pulling down is capable of being adjusted to the reference resistance value;
a second pull-up driver configured to pull up the voltage of the signal output terminal according to a corresponding pull-up signal, whose ON resistance at a time of pulling up is capable of being adjusted to n times the reference resistance value, where n is an integer of two or more; and
a second pull-down driver configured to pull down the voltage of the signal output terminal according to a corresponding pull-down signal, whose ON resistance at a time of pulling down is capable of being adjusted to the n times the reference resistance value.

2. The semiconductor device according to claim 1, further comprising:
a calibration circuit configured to adjust, at a time of calibration, the ON resistance of each of the first pull-up driver and the first pull-down driver to the reference resistance value, and the ON resistance of each of the second pull-up driver and the second pull-down driver to the n times the reference resistance value, by using an external resistor, connected to an external resistor terminal, having the reference resistance value.

3. The semiconductor device according to claim 2, wherein
the calibration circuit outputs a first pull-up calibration signal, a first pull-down calibration signal, a second pull-up calibration signal, and a second pull-down calibration signal,
the ON resistance of the first pull-up driver is adjusted by the first pull-up calibration signal,
the ON resistance of the first pull-down driver is adjusted by the first pull-down calibration signal,
the ON resistance of the second pull-up driver is adjusted by the second pull-up calibration signal, and
the ON resistance of the second pull-down driver is adjusted by the second pull-down calibration signal.

4. The semiconductor device according to claim 3, wherein the calibration circuit comprises:
a first pull-up driver for adjustment configured to pull up a voltage of the external resistor terminal, whose ON resistance is to be adjusted by the first pull-up calibration signal, the first pull-up driver for adjustment having a same configuration as the first pull-up driver;
a second pull-up driver for adjustment configured to pull up a voltage of a first node, whose ON resistance is to be adjusted by the first pull-up calibration signal, the second pull-up driver for adjustment having a same configuration as the first pull-up driver;
a first pull-down driver for adjustment configured to pull down the voltage of the first node, whose ON resistance is to be adjusted by the first pull-down calibration signal, the first pull-down driver for adjustment having a same configuration as the first pull-down driver;
a first control circuit configured to determine the first pull-up calibration signal in such a way that the voltage of the external resistor terminal comes closer to a first reference voltage, and to then determine the first pull-down calibration signal in such a way that the voltage of the first node comes closer to the first reference voltage;
a third pull-up driver for adjustment configured to pull up the voltage of the external resistor terminal, whose ON resistance is to be adjusted by the second pull-up calibration signal, the third pull-up driver for adjustment having a same configuration as the second pull-up driver;
a fourth pull-up driver for adjustment configured to pull up a voltage of a second node, whose ON resistance is to be adjusted by the second pull-up calibration signal, the fourth pull-up driver for adjustment having a same configuration as the second pull-up driver;
a second pull-down driver for adjustment configured to pull down the voltage of the second node, whose ON resistance is to be adjusted by the second pull-down calibration signal, the second pull-down driver for adjustment having a same configuration as the second pull-down driver; and
a second control circuit configured to determine the second pull-up calibration signal in such a way that the voltage of the external resistor terminal comes closer to a second reference voltage corresponding to the n, and to then determine the second pull-down calibration signal in such a way that the voltage of the second node comes closer to the first reference voltage.

5. The semiconductor device according to claim 3, wherein
the first pull-up driver comprises m first unit pull-up drivers, each first unit pull-up driver pulling up the voltage of the signal output terminal, where m is an integer of two or more,
the first pull-down driver comprises m first unit pull-down drivers, each first unit pull-down driver pulling down the voltage of the signal output terminal,
the second pull-up driver comprises m second unit pull-up drivers, each second unit pull-up driver pulling up the voltage of the signal output terminal,
the second pull-down driver comprises m second unit pull-down drivers, each second unit pull-down driver pulling down the voltage of the signal output terminal,
an ON resistance of each of the second unit pull-up drivers is the n times an ON resistance of a corresponding first unit pull-up driver,
an ON resistance of each of the second unit pull-down driver is the n times an ON resistance of a corresponding first unit pull-down driver,
at least one of the first unit pull-up drivers is turned on according to the first pull-up calibration signal,
at least one of the first unit pull-down drivers is turned on according to the first pull-down calibration signal,
at least one of the second unit pull-up drivers is turned on according to the second pull-up calibration signal, and
at least one of the second unit pull-down drivers is turned on according to the second pull-down calibration signal.

6. The semiconductor device according to claim 2, wherein
the calibration circuit outputs a pull-up calibration signal and a pull-down calibration signal,
the ON resistances of the first and second pull-up drivers are adjusted by the pull-up calibration signal, and
the ON resistances of the first and second pull-down drivers are adjusted by the pull-down calibration signal.

7. The semiconductor device according to claim 6, wherein the calibration circuit comprises:
a first pull-up driver for adjustment configured to pull up the voltage of the external resistor terminal, whose ON resistance is to be adjusted by the pull-up calibration signal, the first pull-up driver for adjustment having a same configuration as the first pull-up driver,
a second pull-up driver for adjustment configured to pull up a voltage of a detection node, whose ON resistance is to be adjusted by the pull-up calibration signal, the second pull-up driver for adjustment having a same configuration as the first pull-up driver,
a pull-down driver for adjustment configured to pull down the voltage of the detection node, whose ON resistance is to be adjusted by the pull-down calibration signal, the pull-down driver for adjustment having a same configuration as the first pull-down driver, and
a control circuit configured to determine the pull-up calibration signal in such a way that the voltage of the external resistor terminal comes closer to a reference voltage, and to then determine the pull-down calibration signal in such a way that the voltage of the detection node comes closer to the reference voltage.

8. The semiconductor device according to claim 6, wherein
the first pull-up driver comprises m first unit pull-up drivers, each first unit pull-up driver pulling up the voltage of the signal output terminal, where m is an integer of two or more,
the first pull-down driver comprises m first unit pull-down drivers, each first unit pull-down driver pulling down the voltage of the signal output terminal,
the second pull-up driver comprises m second unit pull-up drivers, each second unit pull-up driver pulling up the voltage of the signal output terminal,
the second pull-down driver comprises m second unit pull-down drivers, each second unit pull-down driver pulling down the voltage of the signal output terminal,
an ON resistance of each of the second unit pull-up drivers is the n times an ON resistance of a corresponding first unit pull-up driver,
an ON resistance of each of the second unit pull-down drivers is the n times an ON resistance of a corresponding first unit pull-down driver,
at least one of the first unit pull-up drivers and at least one of the second unit pull-up drivers are turned on according to the pull-up calibration signal, and
at least one of the first unit pull-down drivers and at least one of the second unit pull-down drivers are turned on according to the pull-down calibration signal.

9. The semiconductor device according to claim 8, wherein
each of the first unit pull-up drivers comprises a first PMOS transistor and a first pull-up resistor that are connected in series between a power supply and the signal output terminal,
each of the second unit pull-up drivers comprises a second PMOS transistor and a second pull-up resistor that are connected in series between the power supply and the signal output terminal,
an ON resistance of the second PMOS transistor of each of the second unit pull-up drivers is n times an ON resistance of the first PMOS transistor of a corresponding first unit pull-up driver,
a resistance value of the second pull-up resistor of each of the second unit pull-up drivers is n times a resistance value of the first pull-up resistor of a corresponding first unit pull-up driver,
each of the first unit pull-down drivers comprises a first NMOS transistor and a first pull-down resistor that are connected in series between the signal output terminal and a ground,
each of the second unit pull-down drivers comprises a second NMOS transistor and a second pull-down resistor that are connected in series between the signal output terminal and the ground,
an ON resistance of the second NMOS transistor of each of the second unit pull-down drivers is n times an ON resistance of the first NMOS transistor of a corresponding first unit pull-down driver, and
a resistance value of the second pull-down resistor of each of the second unit pull-down drivers is n times a resistance value of the first pull-down resistor of a corresponding first unit pull-down driver.

10. The semiconductor device according to claim 8, wherein
each of the first unit pull-up drivers comprises a first PMOS transistor and a first pull-up resistor that are connected in series between a power supply and the signal output terminal,
each of the second unit pull-up drivers comprises n second PMOS transistors and n second pull-up resistors that are connected in series between the power supply and the signal output terminal,
a size of each of the second PMOS transistors is same as a size of a corresponding first PMOS transistor,
a resistance value of each of the second pull-up resistors is same as a resistance value of a corresponding first pull-up resistor,
each of the first unit pull-down drivers comprises a first NMOS transistor and a first pull-down resistor that are connected in series between the signal output terminal and a ground,
each of the second unit pull-down drivers comprises n second NMOS transistors and n second pull-down resistors that are connected in series between the signal output terminal and the ground,
a size of each of the second NMOS transistors is same as a size of a corresponding first NMOS transistor, and
a resistance value of each of the second pull-down resistors is same as a resistance value of a corresponding first pull-down resistor.

11. The semiconductor device according to claim 10, wherein
in each of the second unit pull-up drivers, the n second PMOS transistors are connected in series between the power supply and a first connection node, and the n second pull-up resistors are connected in series between the first connection node and the signal output terminal, and
in each of the second unit pull-down drivers, the n second pull-down resistors are connected in series between the signal output terminal and a second connection node, and the n second NMOS transistors are connected in series between the second connection node and the ground.

12. The semiconductor device according to claim 1, further comprising:
eleven first pull-up drivers; and
eleven first pull-down drivers.

13. The semiconductor device according to claim 12,
wherein the reference resistance value is 300Ω, and the n is two.

14. The semiconductor device according to claim 1, further comprising:
a first driver comprising the first pull-up driver and the first pull-down driver;
a second driver comprising the second pull-up driver and the second pull-down driver; and
an output control circuit configured to select, at a time of a termination operation, according to a termination resistance that is set, a driver to be operated from the first driver and the second driver, and to output the pull-up signal and the pull-down signal in such a way as to turn on both the pull-up driver and the pull-down driver of the driver to be operated.

15. The semiconductor device according to claim 14, wherein
the output control circuit selects, at a time of a data output operation, according to impedance that is set, the driver to be operated from the first and second drivers, and causes the driver to be operated to perform pulling up or pulling down according to output data.

16. A semiconductor device comprising:
three pull-up drivers, each pull-up driver pulling up a voltage of a signal output terminal according to a corresponding pull-up signal, an ON resistance at a time of pulling up of each pull-up driver being capable of being adjusted to n times a predetermined reference resistance value, where n is an integer of two or more;
three pull-down drivers, each pull-down driver pulling down the voltage of the signal output terminal according to a corresponding pull-down signal, an ON resistance at a time of pulling down of each pull-down driver being capable of being adjusted to the n times the reference resistance value; and
a calibration circuit configured to adjust, at a time of calibration, the ON resistance of each of the pull-up drivers and the pull-down drivers to the n times the reference resistance value, by using an external resistor, connected to an external resistor terminal, having the reference resistance value.

17. The semiconductor device according to claim 16,
wherein the calibration circuit comprises:
a first pull-up driver for adjustment configured to pull up a voltage of the external resistor terminal, whose ON resistance is to be adjusted by a pull-up calibration signal, the first pull-up driver for adjustment having a same configuration as the pull-up drivers,
a second pull-up driver for adjustment configured to pull up a voltage of a detection node, whose ON resistance is to be adjusted by the pull-up calibration signal, the second pull-up driver for adjustment having a same configuration as the pull-up drivers,
a pull-down driver for adjustment configured to pull down the voltage of the detection node, whose ON resistance is to be adjusted by a pull-down calibration signal, the pull-down driver for adjustment having a same configuration as the pull-down drivers, and
a control circuit configured to determine the pull-up calibration signal in such a way that the voltage of the external resistor terminal comes closer to a first reference voltage corresponding to the n, and to then determine the pull-down calibration signal in such a way that the voltage of the detection node comes closer to a second reference voltage,
wherein the ON resistances of the pull-up drivers are adjusted by the pull-up calibration signal, and
the ON resistances of the pull-down drivers are adjusted by the pull-down calibration signal.

18. The semiconductor device according to claim 16, further comprising:
twenty-one pull-up drivers; and
twenty-one pull-down drivers.

19. The semiconductor device according to claim 18,
wherein the reference resistance value is 300Ω, and the n is two.
